(19) United States
(12) Patent Application Publication
(10) Pub. No.: US 2006/0054977 A1
(43) Pub. Date: Mar. 16, 2006

(54) Charge storage memory cell

(75) Inventors: Dinesh Somasekhar, Portland, OR (US); Shekhar Borkar, Beaverton, OR (US); Vivek K. De, Beaverton, OR (US); Yibin Ye, Portland, OR (US); Muhammad M. Khellah, Lake Oswego, OR (US); Fabrice Paillet, Hillsboro, OR (US); Stephen H. Tang, Beaverton, OR (US); Ali Keshavarzi, Portland, OR (US); Shih-Lien L. Lu, Portland, OR (US)

Correspondence Address: FLESHNER-KIM, LLP;INTEL CORPORATION, P.O. BOX 221200, CHANTILLY, VA, 20153-1200, US

(73) Assignee: Intel Corporation

(21) Appl. No.: 10/942,019

(22) Filed: Sep. 16, 2004

(51) Int. Cl. H01L 29/76

(52) U.S. Cl. 257/390

(57) ABSTRACT

A memory device is provided that includes a plurality of memory cells where each memory cell includes a source region, a drain region and a floating gate. A coupling bit-line is also provided that extends over at least one column of the plurality of memory cells. The coupling bit-line may be formed on each of the floating gates of memory cells forming the column of the plurality of memory cells. The coupling bit-line may also be formed within a well of each of memory cells forming the column of the plurality of memory cells.

### FIELD

Embodiments of the present invention may relate to memory cells. More particularly, embodiments of the present invention may relate to memory cells that exploit gate leakage.

### BACKGROUND

Storage cells may utilize any one of a plurality of techniques to store binary values in a cell. For example, a dynamic random access memory (DRAM) cell may utilize charge stored in a capacitor for discriminating between a one (“1”) or a zero (“0”). A memory cell, often referred to as a gain cell, may be created by utilizing a gate of a metal-oxide semiconductor field-effect transistor (MOSFET) as a storage element.

The memory cell may perform at least three different operations, namely a READ operation, a WRITE operation and a HOLD operation. A READ operation is an operation in which a value held in the memory cell is externally accessed. A WRITE operation is an operation in which the value held in the memory cell is altered. A HOLD operation is an operation in which the memory cell preserves the stored value. The memory cell may be read by sensing the “strength” (determined by the charge stored) at the gate used to turn ON the device. For an N-MOSFET with the gate charged to a HIGH voltage, the MOSFET may be turned ON strongly. On the other hand, with the gate held at a LOW voltage, the MOSFET may be turned ON weakly.

For this type of gain cell, the WRITE operation may be accomplished by modifying the value stored on the gate. For example, a pass device may be coupled to the gate so that charge may be stored and removed from the gate after turning ON the pass device.

With no path for the charge to leak away, from the gate of the MOSFET, the gain cell may implicitly store a value. For the gain cell, the presence of unavoidable leakage through such a pass device may place a time limit that the cell can hold a value. Thus, retention time may be an important factor for such cells.

### BRIEF DESCRIPTION OF THE DRAWINGS

The foregoing and a better understanding of the present invention may become apparent from the following detailed description of arrangements and example embodiments and the claims when read in connection with the accompanying drawings, all forming a part of the disclosure of this invention. While the foregoing and following written and illustrated disclosure focuses on disclosing arrangements and example embodiments of the invention, it should be clearly understood that the same is by way of illustration and example only and the invention is not limited thereto.

The following represents brief descriptions of the drawings in which like reference numerals represent like elements and wherein:

FIG. 1 shows an array of gain cells according to an example arrangement;

FIG. 2 shows a floating gate memory cell according to an example arrangement;

FIG. 3 shows a floating gate memory cell having a coupling bit-line according to an example embodiment of the present invention;

FIG. 4 shows an array of floating gate memory cells according to an example embodiment of the present invention;

FIG. 5 shows a PMOS floating gate memory cell according to an example embodiment of the present invention;

FIG. 6 shows an array of PMOS floating gate memory cells according to an example embodiment of the present invention; and

FIG. 7 is a system level block diagram according to an example embodiment of the present invention.

### DETAILED DESCRIPTION

In the following detailed description, like reference numerals and characters may be used to designate identical, corresponding or similar components in differing figure drawings. Further, in the detailed description to follow, example sizes/models/values/ranges may be given although the present invention is not limited to the same. Well-known power/ground connections to integrated circuits (ICs) and other components may not be shown within the FIGs. for simplicity of illustration and discussion. Further, arrangements and embodiments may be shown in block diagram form in order to avoid obscuring the invention, and also in view of the fact that specifics with respect to implementation of such block diagram arrangements may be dependent upon the platform within which the present invention is to be implemented. That is, the specifics are well within the purview of one skilled in the art. Where specific details are set forth in order to describe example embodiments of the invention, it should be apparent to one skilled in the art that the invention can be practiced without these specific details.

Further, while values or signals may be described as HIGH (“1”) or LOW (“0”), these descriptions of HIGH and LOW are intended to be relative to the discussed arrangement and/or embodiment. That is, a value or signal may be described as HIGH in one arrangement although it may be LOW if provided in another arrangement, such as with a change in logic. The terms HIGH and LOW may be used in an intended generic sense. Embodiments and arrangements may be implemented with a total/partial reversal of the HIGH and LOW signals by a change in logic.

Further, arrangements and embodiments may be described with respect to a memory array having a plurality of memory cells in a matrix having a plurality of rows and a plurality of columns. The terminology row and column may be reversed as they merely relate to directions.

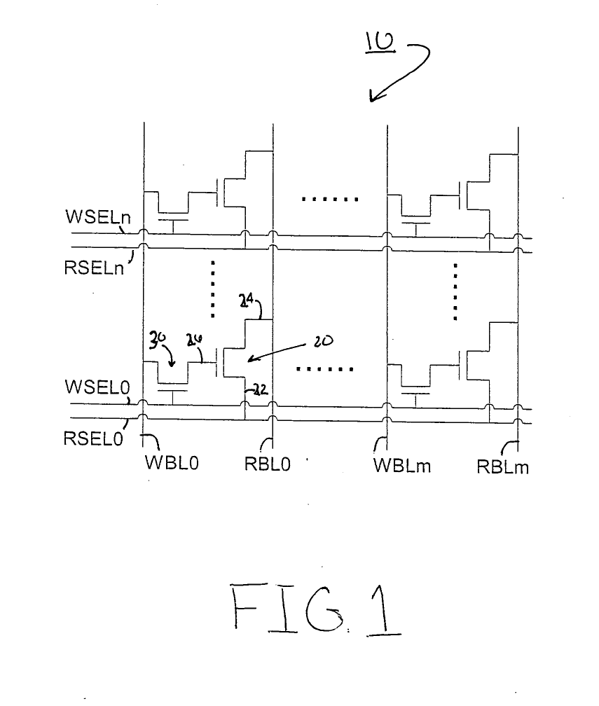

FIG. 1 shows an array 10 of gain cells 20 according to an example arrangement. Other arrangements are also possible. More specifically, FIG. 1 shows a plurality of WRITE BIT LINES (WBL0-WBLm), a plurality of READ BIT LINES (RBL0-RBLm), a plurality of WRITE BIT SELECT LINES (WSEL0-WSELn) and a plurality of READ BIT SELECT LINES (RSEL0-RSELn).

Each of the memory cells 20 within the array 10 may include a source 22, a drain 24 and a gate 26. For ease of illustration, only one of the memory cells is labeled in the array 10. The source 22 of each memory cell 20 may be coupled to a corresponding one of the RSELs, the drain 24 of each memory cell 20 may be coupled to a corresponding one of the RBLs and the gate 26 of each memory cell 20 may be coupled to a corresponding pass transistor (or pass device), such as pass transistor 30.

With thinned gate oxides, a MOSFET, such as the memory cell 20, may exhibit significant tunneling leakage from the gate of the MOSFET to “electrically” isolated conducting structures under the gate. Leakage from the gate may depend on a voltage present on the gate of the MOSFET. The leakage may be exponentially related to the voltage across the gate. For example, with a gate voltage sufficient to form a conducting channel between the source and drain of the MOSFET, the gate leakage may be higher. In the absence of a channel under the gate, the gate leakage may be substantially reduced. In addition to the leakage of the gate to the channel, the gate may leak to the source and drain regions through an overlap region.

For an N-MOSFET, the gate leakage may be low when the gate voltage with respect to the source is less than a threshold voltage of the device. The gate leakage may increase rapidly (i.e., exponentially) as the voltage is increased above a threshold and a channel is formed for the N-MOSFET.

As will be described below, embodiments of the present invention may utilize the dependence of gate leakage to write to the memory cell by setting the MOSFET in a bias condition where the gate leakage is high. The cell may hold a value with the device biased such that the gate leakage is very low. As will be further described, a READ operation may be performed with the device being turned ON and the gate voltage controlling the current drive from the device. Since a channel may be formed during the READ operation, the value held in the cell may be destroyed after the READ operation. Consequently, the cell may exhibit a destructive read-out behavior and may need to be refreshed after various READ operations.

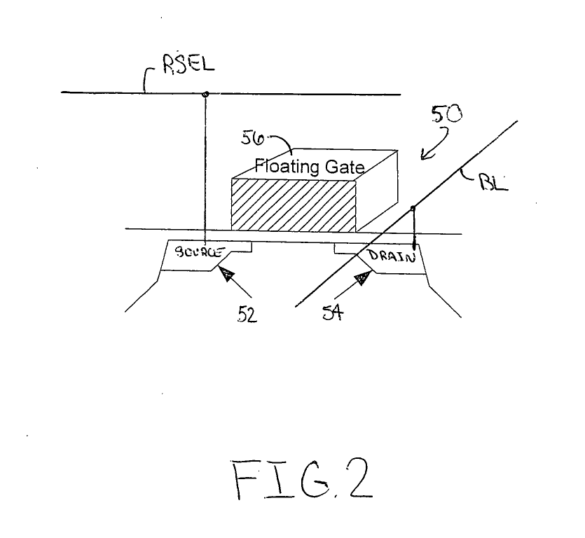

FIG. 2 shows a floating gate memory cell according to an example arrangement. Other arrangements are also possible. More specifically, FIG. 2 shows a gain cell 50 having a source terminal (or source region) 52, a drain terminal (or drain region) 54 and a floating gate terminal (or floating gate) 56. The source terminal 52 may be coupled to a corresponding RSEL and the drain terminal 54 may be coupled to a corresponding BL. A plurality of such cells may be formed into an array (such as shown in FIG. 1) by forming rows of cells sharing RSELs and columns of cells sharing BLs. A capacitive coupling technique may be provided for writing to the floating gate cell.

Embodiments of the present invention may reduce a size of the gain cells (and memory array) by eliminating pass devices (or pass transistors) coupled to the gates of the memory cells. Accordingly, a WRITE operation to a memory cell may be accomplished by utilizing leakage from the gate of the memory cell to the channel or source-drain regions of the MOSFET (i.e., the memory cell).

Embodiments of the present invention may exploit band-to-band gate tunneling to implement a memory cell that allows writing, reading and storing of values. This may be provided by capacitive coupling of the floating gate. The capacitive coupling may occur by utilizing a write bit line (WBL) over the floating gate or by utilizing a write bit line (WBL) implemented in an NWELL of the memory cell. Reading and writing operations may thereby be accomplished using RSEL and WBL. Embodiments of the present invention may thereby exploit the property of the leakage being exponentially related to the voltage on the floating gate.

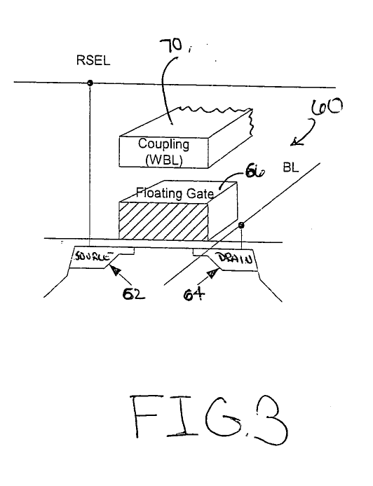

FIG. 3 shows a floating gate memory cell having a coupling bit-line according to an example embodiment of the present invention. Other embodiments and configurations are also within the scope of the present invention. More specifically, FIG. 3 shows a floating gate memory cell 60 having a source terminal (or source region) 62, a drain terminal (or drain region) 64, a floating gate terminal (or floating gate) 66 and a coupling bit-line 70. The source terminal 62 may be coupled to a corresponding RSEL and the drain terminal 64 may be coupled to a corresponding BL.

The coupling bit-line 70 may serve as a low leakage capacitor and may be coupled to the floating gate 66. Such a capacitor may be created by providing a conductive layer (e.g., polysilicon) over the floating gate 66 of the cell 60. In this example embodiment, the coupling bit-line 70 may be a signal line WBL that runs parallel (or substantially parallel) to BL. Accordingly, the WBL may be a common line that runs across the array of memory cells and such that it is over a plurality of corresponding floating gates.

The floating gate 66 may be considered “floating” in the sense that it is not directly contacting a voltage source or signal line (such as BL, RSEL or WBL). The floating gate 66 may be formed of a polysilicon material and the coupling bit-line 70, formed of a double polysilicon, may be formed directly on the floating gate 66. Alternatively, the coupling bit-line 70 may be formed on an interconnect stack over the floating gate 66. As such, the coupling bit-line 70 may be capacitively coupled to the floating gate 66.

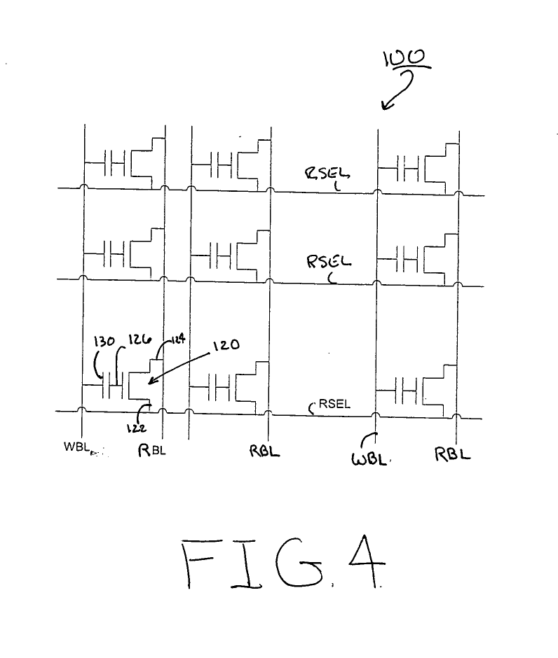

FIG. 4 shows an array 100 of floating gate memory cells 120 according to an example embodiment of the present invention. Other embodiments and configurations are also within the scope of the present invention. More specifically, FIG. 4 shows a plurality of WRITE BIT LINES (WBL), a plurality of READ BIT LINES (RBL) and a plurality of READ BIT SELECT LINES (RSEL).

Each of the memory cells 120 of the array 100 may include a source 122, a drain 124 and a gate 126. For ease of illustration, only one of the memory cells 120 is labeled in the array 100. The source 122 of each memory cell 120 may be coupled to a corresponding one of the RSELs, the drain 124 of each memory cell 120 may be coupled to a corresponding one of the RBLs and the gate 126 of each memory cell 120 may be coupled to a corresponding coupling bit-line 130 (such as the coupling bit-line 70 shown in FIG. 3). The coupling bit-line 130 is shown as a capacitor in FIG. 3. The coupling bit-line 130 may correspond to the WBL. That is, the coupling bit-line may be commonly formed across a plurality of memory cells of the array 130.

More specifically, FIG. 4 shows an array of floating gate memory cells coupled to RBL and WBL. A HOLD operation of each the memory cells may occur when the corresponding memory cell has RBL HIGH, WBL LOW and RSEL HIGH. Additionally, the HOLD operation may occur if RBL, WBL and RSEL are all HIGH.

A WRITE operation of a memory cell (and all cells connected to the same RSEL) may involve the corresponding WBL being LOW. The RSEL for the row being written into may be pulled LOW. This operation may be preserved until a point when the gate discharges by way of gate leakage to the channel and reaches a voltage of approximately a threshold voltage of the memory device. This operation may correspond to a “one” (logic) value being held in the cell. Unaccessed cells in other rows may not be disturbed because the voltage across those cells may be unaltered (i.e., RSEL for the unaccessed cells may remain HIGH, WBL may be LOW and RBL may be HIGH).

To write a “zero” (logic) value into particular cells in a row, the WBL for those corresponding rows may be set HIGH. The coupling from the WBL to the gate may force the gate of all cells coupled to the WBL to be HIGH. For selected cells, the RSEL may be LOW and a channel may be formed if the gate voltage goes sufficiently HIGH. Consequently, gate leakage may increase to a value large enough to discharge the gate back to the threshold voltage of the device. For unselected cells, the RSEL may be HIGH and the coupling may be insufficient to form a channel in the MOSFETs. Consequently, the unselected cells may continue to hold their values.

The RSEL for the selected row may be driven HIGH to a supply voltage VCC. With the source being driven HIGH, the channel between the source region and the drain region may be removed (i.e., the gates for all devices in the selected row was previously a threshold voltage above GROUND) and the gate leakage may become negligible. Coupling from the source and drain regions may force a small rise in the voltage of the gate. However, at the end of RSEL being HIGH, the floating gates in the selected rows may be below VCC.

For cells being written with a “zero”, the WBL may be HIGH and the WBL may be driven LOW. The coupling between the WBL and the floating gates may drive the gates substantially below VCC. After the WRITE operation, memory cells holding a “zero” may have the floating gates at a voltage substantially below VCC while memory cells holding a “one” may have the floating gate closer to VCC.

The retention time of the memory cells may be governed by leakage of charge from the gate. Because the source/drain regions are both HIGH (i.e., the RSEL and RBL are both HIGH in the rest state), then no channel (or substantially no channel) may exist in the MOSFETs, and channel leakage may be eliminated (or substantially reduced). However, the presence of source drain overlap region leakage may cause the gate to charge to VCC. The cell voltage may be destroyed once the gate charges to VCC.

While the above description relates to an isolated capacitor (such as the coupling bit-line 62 shown in FIG. 3) above the floating gate, other positions of the capacitor may also be within the scope of the present invention. For example, an alternative approach may implement the WBL in a well region within P-MOSFETs.

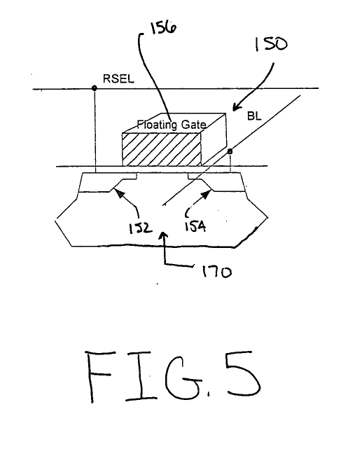

FIG. 5 shows a floating gate memory cell 150 according to an example embodiment of the present invention. Other embodiments and configurations are also within the scope of the present invention. More specifically, FIG. 5 shows a floating gate memory cell 150 having a source terminal (or source region) 152, a drain terminal (or drain region) 154 and a floating gate terminal (or floating gate) 156. The source terminal 152 may be coupled to a corresponding RSEL and the drain terminal 154 may be coupled to a corresponding BL. In this example embodiment, the WBL may be implemented into an NWELL region 170 of the memory cell 150.

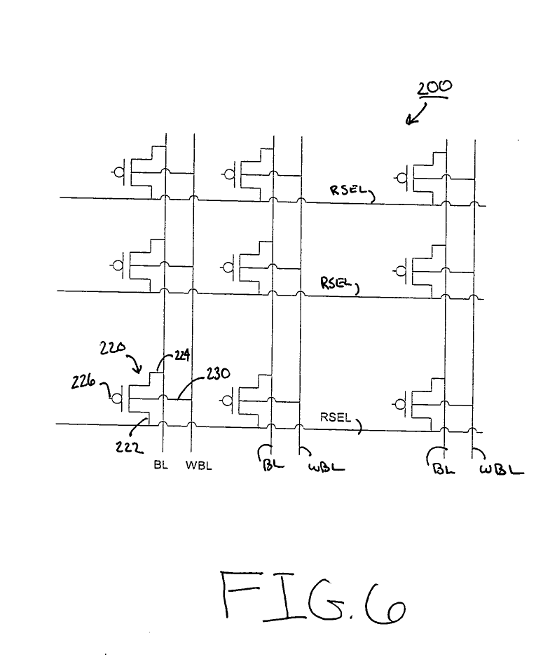

FIG. 6 shows an array 200 of floating gate memory cells 220 according to an example embodiment of the present invention. Other embodiments and configurations are also within the scope of the present invention. More specifically, FIG. 6 shows a plurality of WRITE BIT LINES (WBL), a plurality of READ BIT LINES (RBL) and a plurality of READ BIT SELECT LINES (RSEL). In this embodiment, the memory cells are P-MOSFETs. As shown in FIG. 6, the array 200 may include isolated strips of NWELLs forming the WBLs that run in a similar (or substantially similar) direction to the RBLs. The RSELs may run orthogonal to the RBLs and the WBLs.

Each of the memory cells 220 of the array 200 may include a source 222, a drain 224 and a gate 226. For ease of illustration, only one of the memory cells 220 is labeled in the array 200. The source 222 of each memory cell 220 may be coupled to a corresponding one of the RSELs and the drain 224 of each memory cell 220 may be coupled to a corresponding one of the RBLs. In this example embodiment, the NWELL 230 of each memory cell (i.e., each PMOS transistor) 220 may be coupled to one of the WBLs (or correspond to one of the WBLs).

Operation of the cell with a well WBL may be similar to the methodology discussed above although a polarity of voltages may be reversed. That is, a memory cell may be reset to a “one” by setting the RSEL HIGH for the selected row while the RBL is held LOW (i.e., at ground voltage) and the WBL is held HIGH. The floating gates in the selected row may charge upwards to VCC less the threshold voltage of the P-MOSFET. The WBLs for cells holding a zero (“0”) may be driven to GROUND. The RSEL may be driven LOW (i.e., assuming the HOLD operation for RSEL) with coupling from source to floating gates pulling the gates LOW. The floating gates in the selected cells may assume a voltage somewhat below VCC. The WBLs for cells holding a “zero” may be driven HIGH coupling the floating gates to a HIGH voltage.

While the above description may introduce a separation between the RSELs being toggled initially and the WBL being set for the “zero” cells, this may not always occur as other configurations are also within the scope of the present invention.

Cell disturbance in unselected cells may occur when the WBL is toggled initially for the “zero” cells. In the situation of P-MOSFETs, this may force the gates of unselected cells to couple LOW. To reduce this disturbance, the coupling from RSEL may be much smaller than the coupling from WBL to the floating gate. Under such a scenario, the floating gates may take a value close to VCC for a “one” and a value higher than VCC for a “zero” in the HOLD state. Toggling WBL by a VCC may couple the floating gate to GROUND for a “one” and above GROUND for a “zero”. Consequently, the leakage from the gate of the cell may remain fairly low. READ operations from a row of cells may be accomplished by driving RSEL to a voltage large enough to turn ON the memory devices holding a “one”. This may require the RSEL to have a larger voltage swing during a READ operation as compared to a WRITE operation.

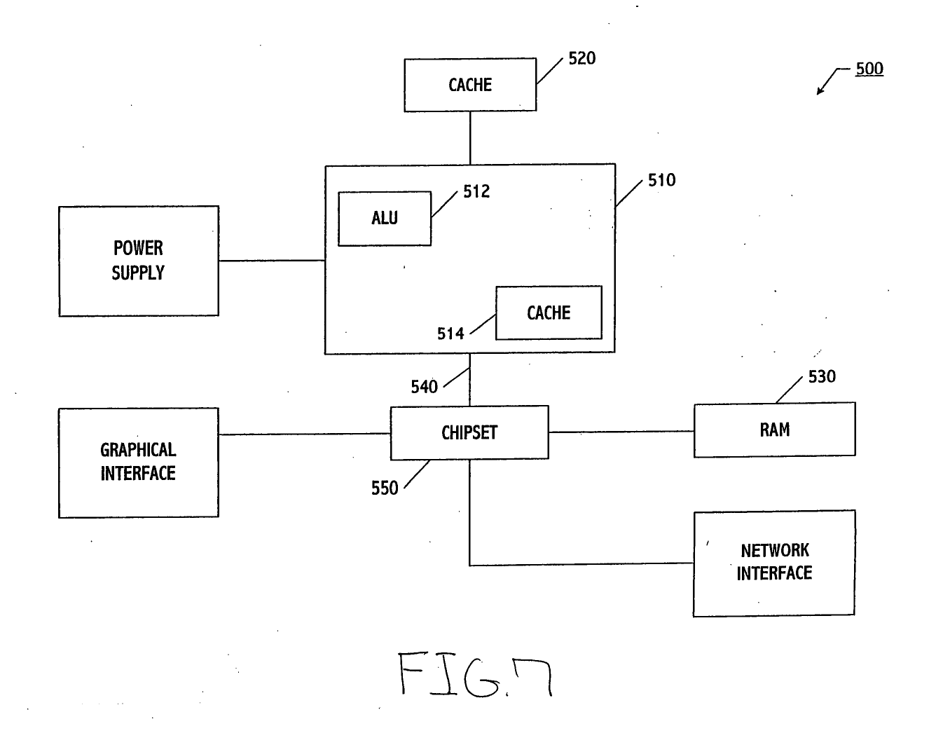

FIG. 7 is a system level block diagram of a system (such as a computer system 500) according to example embodiments of the present invention. Other embodiments and configurations are also within the scope of the present invention. More specifically, the computer system 500 may include a microprocessor 510 that may have many sub-blocks such as an arithmetic logic unit (ALU) 512 and an on-die cache 514. The microprocessor 510 may also communicate to other levels of cache, such as off-die cache 520. Higher memory hierarchy levels such as a system memory (or RAM) 530 may be accessed via a host bus 540 and a chip set 550. In addition, other off-die functional units such as a graphics accelerator and a network interface controller, to name just a few, may communicate with the microprocessor 510 via appropriate busses or ports. For example, the system memory 530, the off-die cache memory 520, and/or the on-die cache memory 514 may include the memory cells and/or memory cell arrays as discussed above.

Systems represented by the various foregoing figures can be of any type. Examples of represented systems include computers (e.g., desktops, laptops, handhelds, servers, tablets, web appliances, routers, etc.), wireless communications devices (e.g., cellular phones, cordless phones, pagers, personal digital assistants, etc.), computer-related peripherals (e.g., printers, scanners, monitors, etc.), entertainment devices (e.g., televisions, radios, stereos, tape and compact disc players, video cassette recorders, camcorders, digital cameras, MP3 (Motion Picture Experts Group, Audio Layer 3) players, video games, watches, etc.), and the like.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments of the present invention have been described with reference to a number of illustrative embodiments thereof, it should be understood that numerous other modifications and embodiments can be devised by those skilled in the art that will fall within the spirit and scope of the principles of this invention. More particularly, reasonable variations and modifications are possible in the component parts and/or arrangements of the subject combination arrangement within the scope of the foregoing disclosure, the drawings and the appended claims without departing from the spirit of the invention. In addition to variations and modifications in the component parts and/or arrangements, alternative uses will also be apparent to those skilled in the art.

What is claimed is:

1. A memory device comprising:
a plurality of memory cells arranged in a plurality of rows and a plurality of columns, each memory cell including a source region, a drain region and a floating gate; and
a coupling bit-line extending over at least one column of the plurality of memory cells, the coupling bit-line to affect a voltage on the floating gate of each memory cell forming the at least one column.

2. The memory device of claim 1, wherein the coupling bit-line is formed on each of the floating gates of each of the memory cells forming the column of the plurality of memory cells.

3. The memory device of claim 1, wherein the coupling bit-line is provided within a well of each of the memory cells forming the column of the plurality of memory cells.

4. The memory device of claim 1, further comprising a read bit line coupled to the drain region of each memory cell forming the column of the plurality of memory cells.

5. The memory device of claim 1, further comprising a read select line coupled to the source region of each memory cell forming at least one row of the plurality of memory cells.

6. The memory device of claim 1, wherein each of the memory cells comprise a metal-oxide semiconductor field-effect transistor (MOSFET).

7. The memory device of claim 1, wherein the memory cells utilize band-to-band gate tunneling to perform read/write operations.

8. The memory device of claim 1, wherein the coupling bit-line comprises polysilicon.

9. A memory array comprising:
a plurality of memory cells arranged in a matrix form having rows and columns, each memory cell having a floating gate;
a bit line extending across a first column of the memory cells;
a read select line extending across a first row of the memory cells; and
a write bit line extending across the first column of memory cells, such that the write bit line is provided relative to the floating gate of each of the memory cells forming the first column of the memory cells.

10. The memory array of claim 9, wherein the coupling bit-line is formed on each of the floating gates of the memory cells forming the first column of the plurality of memory cells.

11. The memory array of claim 9, wherein the coupling bit-line is provided within a well of each of the memory cells forming the first column of the plurality of memory cells.

12. The memory array of claim 9, wherein each of the memory cells comprise a metal-oxide semiconductor field-effect transistor (MOSFET).

13. The memory array of claim 9, wherein the memory cells utilize band-to- band gate tunneling to perform read/write operations.

14. The memory array of claim 9, wherein the coupling bit-line comprises polysilicon.

15. A system comprising:
a processor device to process data;
a memory device to store the data, the memory device comprising:
a plurality of memory cells, each memory cell including a source region, a drain region and a floating gate; and
a coupling write bit-line to capacitively couple with a plurality of the floating gates of memory cells forming at least one column of the plurality of memory cells.

16. The system of claim 15, wherein the coupling write bit-line is formed on the floating gates of each of the memory cells forming the at least one column of the plurality of memory cells.

17. The system of claim 15, wherein the coupling write bit-line is provided within a well of each of the memory cells forming the at least one column of the plurality of memory cells.

18. The system of claim 15, further comprising a read bit line coupled to the drain region of each memory cell forming the at least one column of the plurality of memory cells.

19. The system of claim 15, further comprising a read select line coupled to the source region of each memory cell forming at least one row of the plurality of memory cells.

20. The system of claim 15, wherein memory cells utilize band-to-band gate tunneling to perform read/write operations.

21. The system of claim 15, wherein the coupling write bit-line comprises polysilicon.
